(19) United States
(12) Patent Application Publication
(10) Pub. No.: US 2004/0252474 A1
(43) Pub. Date: Dec. 16, 2004

(54) Integrated circuit stack with lead frames

(76) Inventors: Kwanghak Lee, Fremont, CA (US); Hanjoo Na, Fremont, CA (US); Myeongjin Shin, Fremont, CA (US); Paul Wengseng Heng, Fremont, CA (US)

Correspondence Address: Eugene Oak, Ph.D., J.D., Patent Attorney, 610 S. Van Ness Ave., Los Angeles, CA, 90005, US

(21) Appl. No.: 10/302,704

(22) Filed: Nov. 25, 2002

(51) Int. Cl. G01R 1/00; G05F 1/00; H05K 7/18

(52) U.S. Cl. 361/813; 29/827; 29/840; 29/593

(57) ABSTRACT

A novel multi chip module having increased accuracy of the soldering the integrated circuits (ICs) is provided by utilizing two additional lead frames and turning over the first lead frame soldered IC and stacking secondary IC thereon. Arrays of the first lead frames are mounted on a top tray guided by tooling pins. Solder pastes are printed on the first lead frames. Arrays of the second lead frames are placed on the first lead frames guided with tooling pins. Another layer of solder pastes are printed on the second lead frames. Thermal conductive glue is dispensed on the central portions of the first lead frames. ICs, which become the “bottom ICs” later, are placed on the central portions of the first lead frames upside down by a pick/place machine. After heat treatment, inspection and repair, the bottom ICs are mounted in a pocket on a bottom tray facing the first lead frames upside. Another layer of solder pastes are printed on the first lead frames. Other ICs, which become the “top ICs”, are placed on the first lead frames. Secondary heat treatment, inspection and repairing procedures are executed. Exact position of the solder paste and leads of the IC's are matched by the pick/position machine. The noble structure of this invention enables maintaining the original ICs' characters without deforming at a high production rate.

This invention relates to a structure of a multi chip module utilizing two additional lead frames.

### BACKGROUND OF THE INVENTION

As the needs for high density IC boards increases, many kind of stacking methods for connecting vertically piled ICs have been developed. Regardless of the connecting routes, a lead of one IC is connected to the other IC's lead by soldering. However, it is very hard to put exact amount of solder at the exact position on the shoulder area of the leads of the “bottom” IC. Many companies deformed the leads of the original IC into “J” type or “S” type to increase the shoulder area. Nevertheless, such deformation of IC's leads may result in the change of the characteristic function of the original IC. It is the intend of this invention to provide a novel structure for increasing the accuracy of soldering without deforming the leads of the original ICs.

1. Field of the Invention

This invention relates to a structure of multi chip module having increased accuracy of the soldering the ICs with two additional lead frames by utilizing turning over technique.

2. Description of the Prior Arts

U.S. Pat. No. 6,443,355 to Tsurusaki illustrates a soldering method and apparatus in which the substrate board is inverted for soldering the other side of the circuit board. However, this art is not developed for the micro-scale soldering the leads to leads in multi chip packing procedure.

U.S. Pat. No. 6,313,998 to Kledzik, et al. illustrates a circuit board assembly having integrated circuit packages vertically arranged. A package carrier having a plurality of carrier leads and a secondary mounting pad array on an upper surface thereof, covers the first package. Each lead of the carrier is coupled to a different pad of the secondary array and is conductively bonded to the second portion of a different mounting pad of the primary array. Each lead of a second integrated circuit package is conductively bonded to a different mounting pad of the secondary mounting pad array.

U.S. Pat. No. 6,084,293 to Ohuchi illustrates a stack type semiconductor device, front ends of leads provided at two sides of a first semiconductor device are bent inward to hold a second semiconductor device stacked at the rear surface of the first semiconductor device.

U.S. Pat. No. 6,028,352 to Eide illustrates an IC stack utilizing secondary lead frames. Each layer is formed by mechanically and electrically joining an IC-containing TSOP with an external lead frame. Each lead frame contains conductors which are disposed to connect with TSOP leads, transpose signals to other locations on the periphery of the TSOP, and/or connect with other layers in the stack.

U.S. Pat. No. 5,978,227 to Burns illustrates an integrated circuit packages having an externally mounted lead frame having bifurcated distal lead ends.

U.S. Pat. No. 5,960,539 to Burns describe a method of making a high-density IC module having complex electrical interconnection.

U.S. Pat. No. 5,514,907 to Moshayedi illustrates a multi-chip memory module comprising multiple standard, surface-mount-type memory chips stacked on top of each other, and a pair of printed circuit boards mounted on opposite sides of the memory chips to electrically interconnect the memory chips.

All of the prior arts illustrate soldering leads of an IC to the other ICs. However, none of the prior arts illustrates a soldering method turn upside down of the bottom located IC to increase the accuracy of soldering IC leads and additional lead frames.

### SUMMARY OF THE INVENTION

Therefore, it is the purpose of this invention to provide a novel multi chip module having increased accuracy of the soldering the integrated circuits (ICs) by utilizing two additional lead frames and turning over the first lead frame soldered IC and stacking secondary IC thereon. Arrays of the first lead frames are mounted on a top tray guided by tooling pins. Solder pastes are printed on the first lead frames. Arrays of the second lead frames are placed on the first lead frames guided with tooling pins. Another layer of solder pastes are printed on the second lead frames. Thermal conductive glue is dispensed on the central portions of the first lead frames. ICs, which become the “bottom ICs” later, are placed on the central portions of the first lead frames upside down by a pick/place machine. After heat treatment, inspection and repair the bottom ICs are mounted in a pocket on a bottom tray facing the first lead frames upside. Another layer of solder pastes are printed on the first lead frames. Other ICs, which become the “top ICs”, are placed on the first lead frames. Secondary heat treatment, inspection and repairing procedures are executed. Exact position of the solder paste and leads of the IC's are matched by the pick/position machine. The noble structure of this invention enables maintaining the original ICs' characters without deforming at a high production rate.

### BRIEF DESCRIPTION OF THE DRAWINGS

FIG. 1 is an exploded isomeric view of the multi-chip module of this invention.

FIG. 2 is a cross sectional view of the multi-chip module of this invention.

FIG. 3 is a structure drawing of the lead frame 1 used for this invention.

FIG. 3-a is a structure drawing of a strip of the lead frame 1 used for this invention.

FIG. 4 is a structure drawing of the lead frame 2 used for this invention.

FIG. 4-a is a structure drawing of a strip of the lead frame 2 used for this invention.

FIG. 5 is a schematic drawing of the lead frame 1 and lead frame 2 mounted on top tray.

FIG. 6 is a schematic drawing of the “bottom IC” mounted upside down position on the lead frames on the top tray.

FIG. 7 is a schematic drawing of the “bottom IC” (1b) and soldered frames mounted up right position in the mounting pocket on the bottom tray. is a schematic drawing of the “bottom IC” and soldered frames mounted up right position in the mounting groove on the bottom tray.

### DETAILED DESCRIPTION OF THE PREFERRED EMBODIMENTS

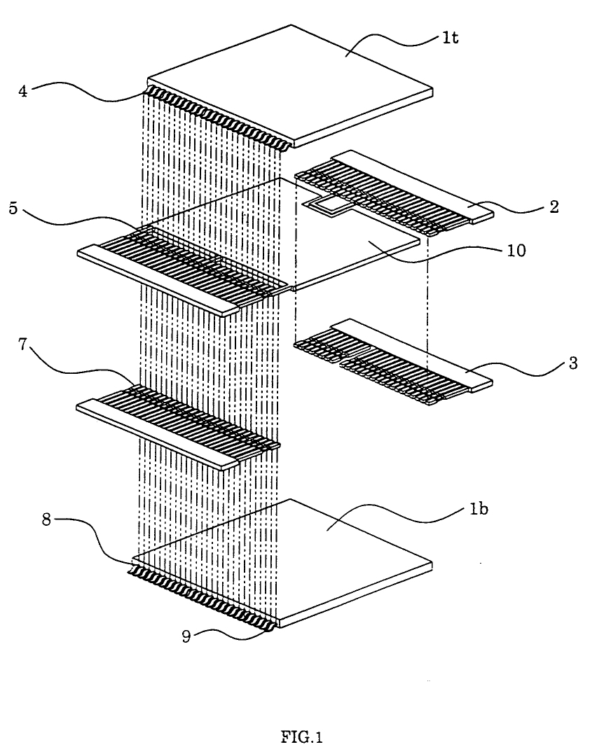

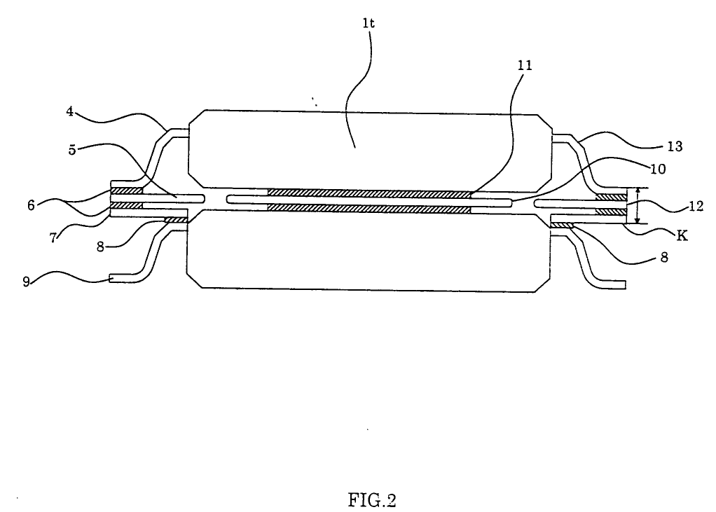

FIG. 1 is an exploded isomeric view of the multi-chip module of this invention. Two integrated circuits “top IC” (1t) and “bottom IC” (1b) are connected by lead frame 1 (2) and lead frame 2(3). As shown in FIG. 2, the cross sectional view of the multi-chip module of this invention, leads (4) of the “top IC” (1t) are soldered to the pads (5) of the lead frame 1(2) with solder pastes (6). The pads (5) of the lead frame 1(2) are again soldered on to the pads (7) of the lead frame 2(3). Then these pads (7) of the lead frame 2(3) are soldered on to the shoulder (8) of the leads (9) of the “bottom IC” (1b). The center part (10) of the lead frame 1(2) is adhered to the both ICs with thermal conductive glue (11).

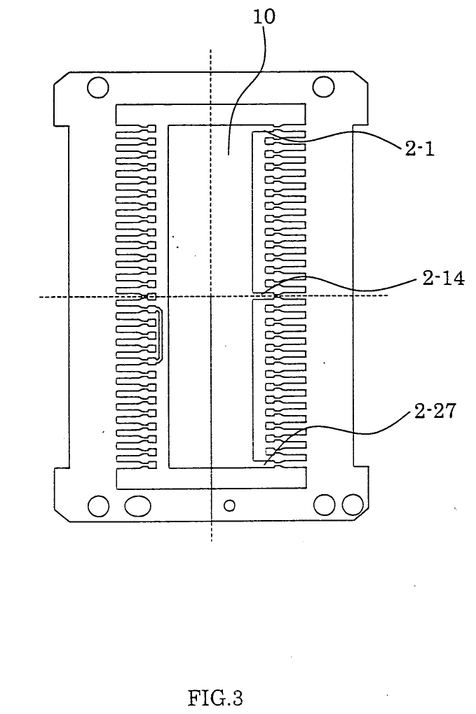

FIG. 3 is a structural drawing of the lead frame 1(2) used for this invention and FIG. 3-a is a drawing of a strip of the lead frame 1. In real process, a strip having eight lead frames are used. Some of the pads (2-1, 2-14 and 2-27) are connected to the central part (10) to connect the “top IC” (1t) to the ground pin of the “bottom IC” (1b). At the same time heats developed in the both ICs (1b and 1t) are conducted to the leads ((4), (9)) of ICs through the connected pads and radiated to the air.

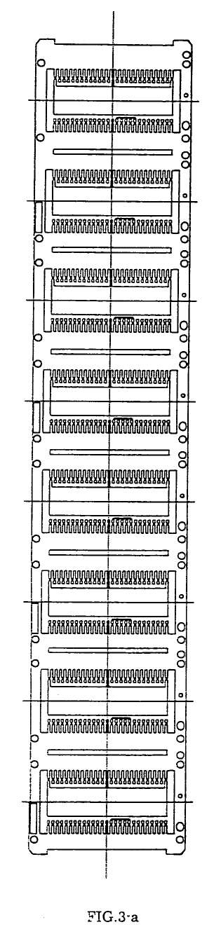

FIG. 4 is a structural drawing of the lead frame 2 used for this invention and FIG. 4-a is a structure drawing of a strip of the lead frame 2. A stip having eight lead frames on it is used in real process. The role of this lead frame 2 (3) is to match the distance (12) between the foot side (13) of the leads (4) of the “top IC” (1t) and shoulder (8) of the leads (9) of the “bottom IC” (1b).

As shown above, the leads of the original ICs are not deformed. It makes the procedure of this invention simpler than many prior arts. However, direct soldering on the shoulder (8) of the leads (9) of the “bottom IC” (1b) is very hard. Upside down technique of this invention is provided to increase the accuracy of this step.

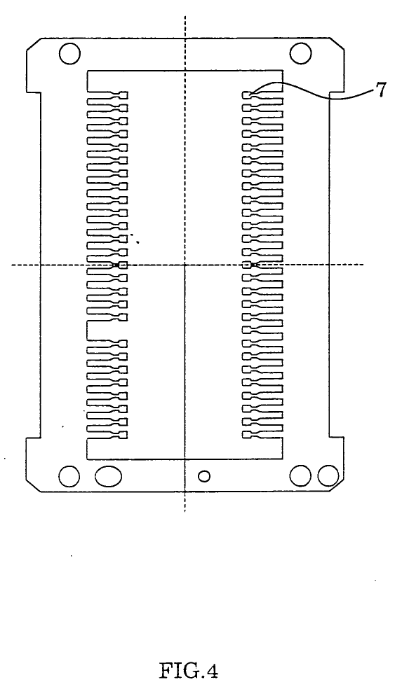

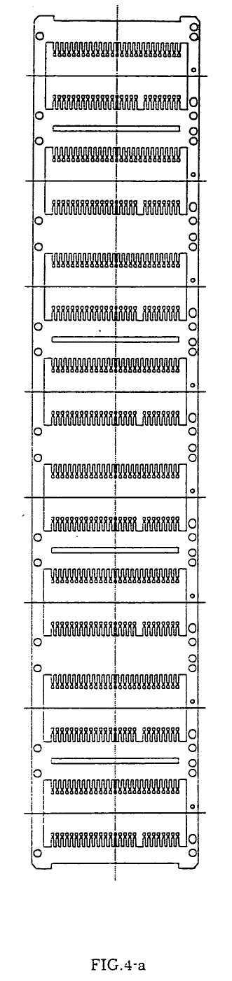

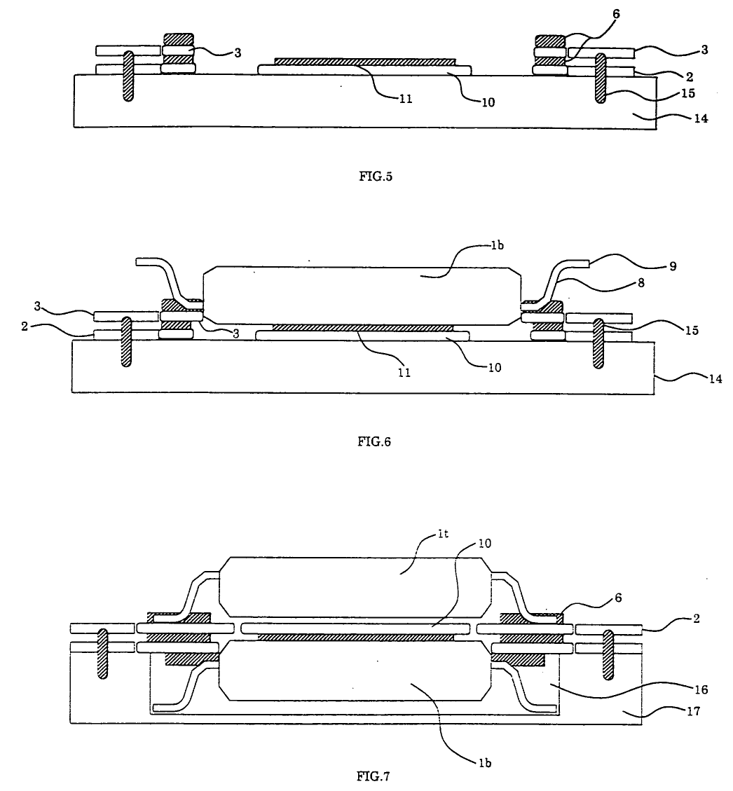

Followings are the description of the upside down technique. FIG. 5 is a schematic drawing of the lead frame 1(2) and lead frame 2(3) mounted on top tray (14). When the materials are ready, place the lead frame 1(2) on the top tray (14) with tooling pins (15). Print solder pastes (6) on the lead frame 1(2) using an auto printer with stencil, which is not shown in this invention. Place the lead frame 2(3) on the lead frame 1(2) guided with tooling pins (15) in each lead. Print solder pastes (6) on the lead frame 2(3) using an auto printer with stencil. Dispense thermal conductive glue (11) on the central part (10) of the lead frame 1(2). Place the “bottom ICs” (1b) on each lead frames utilizing an auto pick/place machine, which is not shown in this invention. FIG. 6 is a schematic drawing of the “bottom IC” mounted upside down position on the lead frames on the top tray. Expose the “bottom IC” placed on the lead frame 1(2) and 2(3) to a programmed temperature profile. Solder troubles are detected using 20 times optical microscope. Detected troubles including improper soldering are repaired. Place the semi-assembled IC (1-b) and lead frames (2), (3) in the pocket (16) on the bottom tray (17). FIG. 7 is a schematic drawing of the “bottom IC” (1b) and soldered frames mounted up right position in the mounting pocket on the bottom tray. Print solder pastes (6) on the lead frame 1(2) with an auto printer of 0.15 mm stencil. Place the “top IC” (1t) on the lead frame 1(2) by auto pick/place machine matching each leads (4) of “top IC”(1t) to pads of lead frame 1(2). After exposing the assembled ICs to a programmed heat treatment, repeat visual inspection and repair. Chemical cleaning, trim and leads cutting and labeling are followed. After the final visual inspection; repair or deoxidizing is followed.

What is claimed is

1. A means of multi chip module having increased accuracy of the soldering the integrated circuits (ICs) by utilizing first lead frame and second lead frame and by utilizing turning over method, which consists of 17 key steps of; 1) mounting first lead frame on the top-tray, 2) printing solder on the first lead frame, 3) mounting second lead frame on the first lead frame where solder is printed, 4) printing solder on the second lead frame, 5) dispensing a thermal conductive glue on the central part of the first lead frame, 6) placing a “bottom IC” on the glued central part of the first lead frame facing the legs of leads upside and shoulder of leads locating on the solder printed on the second lead frame, 7) heat treating, 8) visual inspecting, 9) repairing if necessary, 10) mounting the semi-assembled lead frames and the “bottom IC”, prepared in step 1) to 6), in the pocket on the bottom tray with upside down, 11) printing solder on the first lead frame, which is the opposite site in the step 2), 12) place top IC on the first lead frame where solder is printed, 13) heat treating, 14) visual inspection, 15) repair if necessary, 16) chemical cleaning, 17) cutting leads.

2. The first lead frame, in claim 1, has grounding leads, which connect the central part to the grounding lead of the “bottom IC”.

3. The first and second lead frame, in claim 1, has unit of 6 to 11 on each strip.

4. The pocket, in claim 1 step 10), has depth equal to the lead height of the “bottom IC”.

5. The pocket, in claim 1 step 10), has dimension equal to the dimension of the “bottom IC”.

6. The “bottom IC”, in claim 1 step 10), faces opposite direction to that in step 6).
